(19) United States
(12) Patent Application Publication
(10) Pub. No.: US 2015/0107760 A1
(43) Pub. Date: Apr. 23, 2015

(54) CARRIER AND METHOD OF MANUFACTURING PRINTED CIRCUIT BOARD USING THE SAME

(71) Applicant: SAMSUNG ELECTRO-MECHANICS CO., LTD., Suwon-si (KR)

(72) Inventors: Jin Seok Moon, Suwon-si (KR); Dae Hui Jo, Suwon-si (KR); Keung Jin Sohn, Suwon-si (KR); Seong Hyun Yoo, Suwon-si (KR)

(73) Assignee: SAMSUNG ELECTRO-MECHANICS CO., LTD., Suwon-si (KR)

(21) Appl. No.: 14/160,244

(22) Filed: Jan. 21, 2014

(30) Foreign Application Priority Data
Oct. 21, 2013 (KR) 10-2013-0125198

(51) Int. Cl. H05K 3/46; H05K 1/03

(52) U.S. Cl. CPC H05K 3/4682; H05K 1/036; H05K 1/0366; H05K 1/0373
USPC 156/247; 428/626

(57) ABSTRACT

Disclosed herein are a carrier and a method of manufacturing a printed circuit board using the same. More specifically, in the carrier according to the present invention, the carrier has characteristics of a coefficient of thermal expansion (CTE), a glass transition temperature (Tg), and a storage modulus which are improved by an insulating layer including an epoxy resin and a liquid crystal oligomer. In addition, a first metal layer is formed on the insulating layer, such that the printed circuit board stacked on one surface or both surfaces of the carrier may be protected from deformation by physical impact and the warpage phenomenon may be minimized.

### CROSS REFERENCE TO RELATED APPLICATION

This application claims the benefit of Korean Patent Application No. 10-2013-0125198, filed on Oct. 21, 2013, entitled “Carrier and Method of Manufacturing Printed Circuit Board using the Same”, which is hereby incorporated by reference in its entirety into this application.

### BACKGROUND OF THE INVENTION

1. Technical Field

The present invention relates to a carrier and a method of manufacturing a printed circuit board using the same.

2. Description of the Related Art

In accordance with an advancement of an electronic device, a printed circuit board has gradually become light, thin, and small. In order to satisfy these demands, the printed circuit board has more complex and high dense wirings. As such, electrical, thermal, and mechanical characteristics required by the printed circuit board are considered as more important factors.

A carrier has a configuration comprised of a metal layer serving as a circuit wiring of the printed circuit board and a core layer serving as a support. The core layer has been made of a polymer and has been required of several characteristics such as a modulus, a coefficient of thermal expansion, a glass transition temperature, thickness uniformity, and the like. In addition, the core layer needs to be manufactured so as to be easily separated after it is bonded to a shiny surface of the metal layer.

If hardness of the above-mentioned carrier itself is low, defect may be caused by a warpage phenomenon when constituting upper and lower stacked structure. In order to prevent this problem, a modulus and heat-resisting property of a thermosetting polymer resin is considered an important factor, and upon a thermosetting reaction, a network and a curing density between polymer resin chains constituting a polymer structure and a carrier composition closely influence.

Meanwhile, Patent Document 1 discloses a release paper for a resin base printed board. However, there is a limitation in forming a sufficient mutual network between the respective compositions of the resin included in the release paper. As a result, it is difficult to improve characteristics of the coefficient of thermal expansion, the glass transition temperature, and a storage modulus.

Patent Document 1 Japanese Patent Laid-Open Publication No. 2001-225340

### SUMMARY OF THE INVENTION

The present invention has been made in an effort to provide a carrier for a printed circuit board having characteristics of a coefficient of thermal expansion (CTE), a glass transition temperature (Tg), and a storage modulus which are improved by an insulating layer containing an epoxy resin and a liquid crystal oligomer.

The present invention has been made in an effort to provide a method of manufacturing a printed circuit board manufactured by stacking at least one build-up layer on one surface or both surfaces of the carrier.

According to a preferred embodiment of the present invention, there is provided a carrier, including: an insulating layer; a first metal layer formed on one surface or the other surface of the insulating layer; and a second metal layer formed on one surface or the other surface of the first metal layer, wherein the insulating layer includes an epoxy resin and a liquid crystal oligomer (LCO).

The first metal layer may have a shiny surface bonded to the insulating layer.

The second metal layer may have a matte surface of the first metal layer bonded thereto.

The insulating layer may be an insulating film or a prepreg.

The prepreg may include inorganic fiber or organic fiber.

The inorganic fiber or organic fiber may be at least one selected from glass fiber, carbon fiber, polyparaphenylenebenzobisoxazole fiber, thermotropic liquid crystal polymer fiber, lyotropic liquid crystal polymer fiber, aramid fiber, polypyridobisimidazole fiber, polybenzothiazole fiber, and polyacrylate fiber.

The first metal layer may have a thickness thicker than that of the second metal layer.

The first metal layer and the second metal layer may be made of copper (Cu).

The epoxy resin may be at least one selected from a naphthalene-based epoxy resin, a bisphenol A-type epoxy resin, a bisphenol F-type epoxy resin, a phenol novolac epoxy resin, a cresol novolac epoxy resin, a rubber-modified epoxy resin, and a phosphate-based epoxy resin.

The liquid crystal oligomer may be represented by the following Chemical Formula 1,

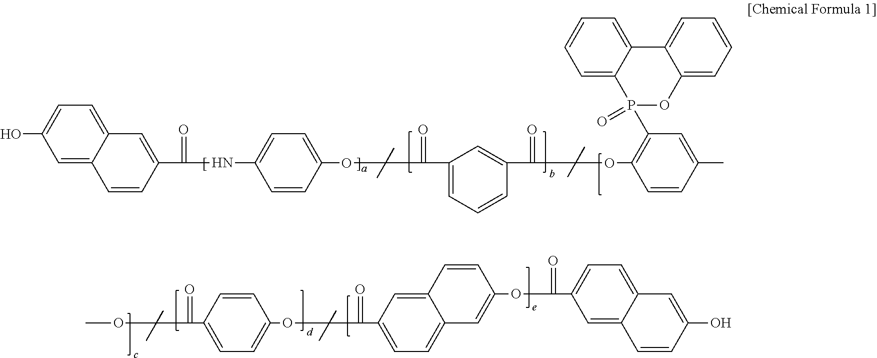

where a is an integer of 13 to 26, b is an integer of 13 to 26, c is an integer of 9 to 21, d is an integer of 10 to 30, and e is an integer of 10 to 30.

The insulating layer may further include an inorganic filler.

The organic filler may be at least one selected from silica (SiO₂), alumina (Al₂O₃), barium sulfate (BaSO₄), talc, aluminum hydroxide (AlOH₃), magnesium hydroxide (Mg(OH)₂), calcium carbonate (CaCO₃), magnesium carbonate (MgCO₃), magnesium oxide (MgO), boron nitride (BN), aluminum borate (AlBO₃), barium titanate (BaTiO₃), and calcium zirconate (CaZrO₃).

According to another preferred embodiment of the present invention, there is provided a method of manufacturing a printed circuit board, the method including: preparing a carrier including an insulating layer, a first metal layer formed on one surface or the other surface of the insulating layer, and a second metal layer formed on one surface or the other surface of the first metal layer, the insulating layer including an epoxy resin and a liquid crystal oligomer (LCO); forming at least one build-up layer including build-up insulating layers and build-up circuit layers on the second metal layer; and separating the insulating layer and the first metal layer from a stacked body having the build-up layer formed thereon.

The epoxy resin may be at least one selected from a naphthalene-based epoxy resin, a bisphenol A-type epoxy resin, a bisphenol F-type epoxy resin, a phenol novolac epoxy resin, a cresol novolac epoxy resin, a rubber-modified epoxy resin, and a phosphate-based epoxy resin.

The liquid crystal oligomer may be represented by the following Chemical Formula 1,

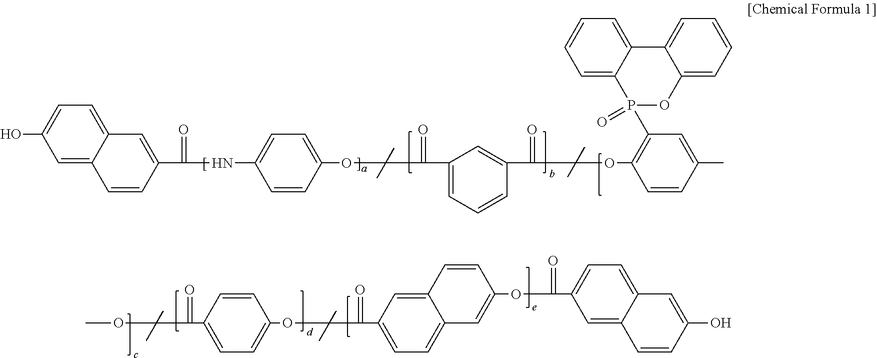

where a is an integer of 13 to 26, b is an integer of 13 to 26, c is an integer of 9 to 21, d is an integer of 10 to 30, and e is an integer of 10 to 30.

The insulating layer may be an insulating film or a prepreg.

In the forming of the first metal layer, a shiny surface of the first metal layer may be bonded to the insulating layer.

In the forming of the second metal layer, a matte surface of the first metal layer may be bonded to the second metal layer.

The separating of the insulating layer and the first metal layer from the stacked body may include: separating the insulating layer from the first metal layer, and separating the first metal layer from the second metal layer.

### BRIEF DESCRIPTION OF THE DRAWINGS

The above and other objects, features and advantages of the present invention will be more clearly understood from the following detailed description taken in conjunction with the accompanying drawings, in which:

FIG. 1 is a cross-sectional view of a carrier according to a preferred embodiment of the present invention; and

FIGS. 2 to 6 are cross-sectional views showing a manufacturing process sequence for describing a method for manufacturing a printed circuit board according to another preferred embodiment of the present invention.

### DESCRIPTION OF THE PREFERRED EMBODIMENTS

The objects, features and advantages of the present invention will be more clearly understood from the following detailed description of the preferred embodiments taken in conjunction with the accompanying drawings. Throughout the accompanying drawings, the same reference numerals are used to designate the same or similar components, and redundant descriptions thereof are omitted. Further, in the following description, the terms “first”, “second”, “one side”, “the other side” and the like are used to differentiate a certain component from other components, but the configuration of such components should not be construed to be limited by the terms. Further, in the description of the present invention, when it is determined that the detailed description of the related art would obscure the gist of the present invention, the description thereof will be omitted.

Hereinafter, preferred embodiments of the present invention will be described in detail with reference to the accompanying drawings.

Carrier

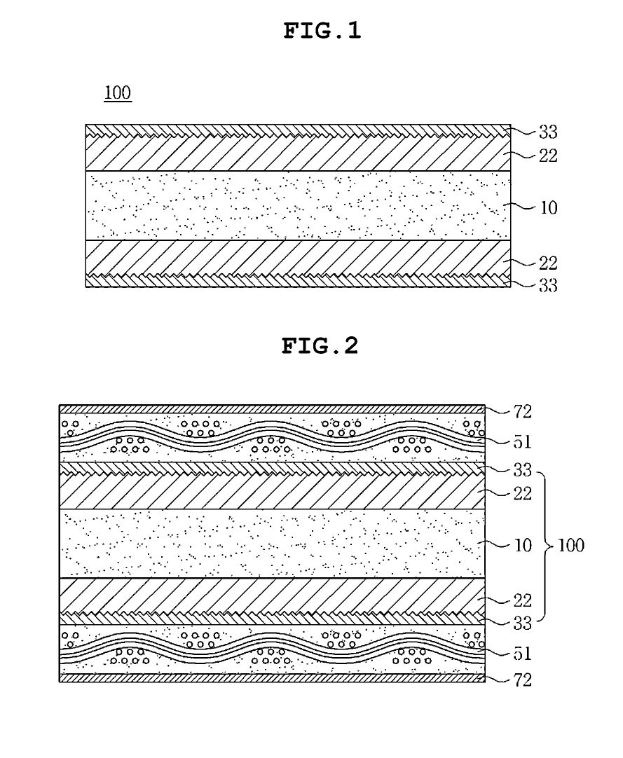

FIG. 1 is a cross-sectional view of a carrier according to a preferred embodiment of the present invention.

Referring to FIG. 1, the carrier 100 according to the preferred embodiment of the present invention may be configured to include an insulating layer 10, a first metal layer 22 formed on one surface or the other surface of the insulating layer 10, and a second metal layer 33 formed on one surface or the other surface of the first metal layer 22, wherein the insulating layer 10 may include an epoxy resin and a liquid crystal oligomer (LCO).

The insulating layer 10 of the carrier 100 may include a resin composition and may include the epoxy resin and the liquid crystal oligomer in order to improve characteristics of a coefficient of thermal expansion, a glass transition temperature, and a storage modulus. Since the insulating layer 10 including the epoxy resin and the liquid crystal oligomer has excellent heat-resisting property and modulus, it is not likely to be deformed by heat or physical force from the outside.

The epoxy resin is not particularly limited, but may be included by 8 to 40 parts by weight per 100 parts by weight of the resin composition of the insulating layer 10. In the case in which the usage of the epoxy resin is below 8 parts by weight, handling property of the resin composition tends to be degraded, and in the case in which the usage of the epoxy resin exceeds 40 parts of weight, an addition amount of other components becomes relatively small, such that characteristic of the coefficient of thermal expansion of the resin composition may be degraded.

The epoxy resin may be at least one selected from a naphthalene-based epoxy resin, a bisphenol A-type epoxy resin, a bisphenol F-type epoxy resin, a phenol novolac epoxy resin, a cresol novolac epoxy resin, a rubber-modified epoxy resin, and a phosphate-based epoxy resin, but is not particularly limited thereto.

The liquid crystal oligomer may be represented by the following Chemical Formula 1, where a hydroxyl group and the epoxy resin which are present at both ends are bonded by a nucleophilic addition reaction to thereby form a network connected to each other, thereby making it possible to show high modulus and excellent heat-resisting property.

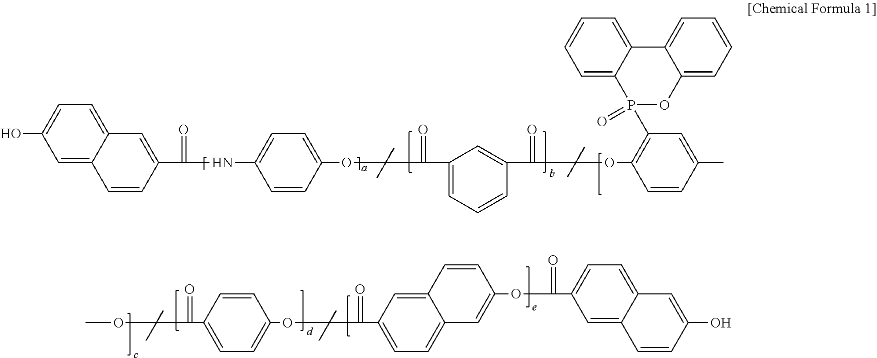

where a is an integer of 13 to 26, b is an integer of 13 to 26, c is an integer of 9 to 21, d is an integer of 10 to 30, and e is an integer of 10 to 30.

The liquid crystal oligomer is not particularly limited, but may be included by 12 to 60 parts by weight per 100 parts by weight of the resin composition of the insulating layer 10. In the case in which the usage of the liquid crystal oligomer is below 12 parts of weight, characteristics of the coefficient of thermal expansion and the glass transition temperature of the resin composition tend to be insignificant, and in the case in which the usage of the liquid crystal oligomer exceeds 60 parts of weight, mechanical property of the resin composition may be degraded.

A number average molecular weight of the liquid crystal oligomer is 2500 to 6500 g/mol. Here, in the case in which the number average molecular weight of the liquid crystal oligomer is below 2500 g/mol, mechanical property may be degraded and in the case in which the number average molecular weight of the liquid crystal oligomer exceeds 6500 g/mol, solubility may be degraded.

In addition, the insulating layer 10 may further include an inorganic filler in order to improve characteristic of the coefficient of thermal expansion. The inorganic filler is not particularly limited, but may be included by 1 to 80 parts by weight per 100 parts by weight of the resin composition of the insulating layer 10. In the case in which the usage of the inorganic filler is below 1 part of weight, the coefficient of thermal expansion of the resin composition tends to be increased, and in which the usage of the inorganic filler exceeds 80 parts of weight, adhesion strength may be degraded.

The inorganic filler may be at least one selected from silica (SiO₂), alumina (Al₂O₃), barium sulfate (BaSO₄), talc, aluminum hydroxide (AlOH₃), magnesium hydroxide (Mg(OH)₂), calcium carbonate (CaCO₃), magnesium carbonate (MgCO₃), magnesium oxide (MgO), boron nitride (BN), aluminum borate (AlBO₃), barium titanate (BaTiO₃), and calcium zirconate (CaZrO₃), but is not particularly limited thereto.

The insulating layer 10 of the carrier 100 according to the preferred embodiment of the present invention may be an insulating film or a prepreg. In addition, the prepreg may include inorganic fiber or organic fiber.

The inorganic fiber or organic fiber may be at least one selected from glass fiber, carbon fiber, polyparaphenylenebenzobisoxazole fiber, thermotropic liquid crystal polymer fiber, lyotropic liquid crystal polymer fiber, aramid fiber, polypyridobisimidazole fiber, polybenzothiazole fiber, and polyacrylate fiber, but is not particularly limited thereto.

The first metal layer 22 of the carrier 100 according to the preferred embodiment of the present invention may be formed so that a shiny surface of the first metal layer 22 is bonded to the insulating layer 10. The shiny surface of the first metal layer 22, which is a smooth portion, may be bonded to the insulating layer 10 and may be easily separated from the insulating layer 10. In the case in which the first metal layer 22 is formed on the insulating layer 10 and an additional build-up layer 80 is stacked on one surface of the other surface of the carrier 100, deformation caused by physical impact may be prevented and a warpage phenomenon may be minimized.

The second metal layer 33 of the carrier 100 according to the preferred embodiment of the present invention may be formed so that a matte surface of the first metal layer 22 is bonded to the second metal layer 33. The matte surface of the first metal surface 22, which is a rough and matte surface having roughness formed thereon, may be easily separated from the second metal layer 33 due to weak adhesive force between the metals even when being bonded to the second metal layer 33.

The first metal layer 22 may have a thickness thicker than that of the second metal layer 33. Since the first metal layer 22 provides protection, it may be relatively thicker than the second metal layer 33.

In addition, as a material including the first metal layer 22 and the second metal layer 33, copper may be used when taking into account of aspects of economic and electrical conductivity.

Method of Manufacturing Printed Circuit Board

FIGS. 2 to 6 are cross-sectional views showing a manufacturing process sequence for describing a method for manufacturing a printed circuit board according to another preferred embodiment of the present invention.

Referring to FIG. 2, the method of manufacturing the printed circuit board according to another preferred embodiment of the present invention may include preparing a carrier 100 including an insulating layer 10, a first metal layer 22 formed on one surface or the other surface of the insulating layer 10, and a second metal layer 33 formed on one surface or the other surface of the first metal layer 22, wherein the insulating layer 10 includes an epoxy resin and a liquid crystal oligomer (LCO), and forming a build-up layer 80 including build-up insulating layers 51 and 53 and build-up circuit layers 72 and 74 on the second metal layer 33.

The insulating layer 10 of the carrier 100 may include a resin composition and may include the epoxy resin and the liquid crystal oligomer in order to improve characteristics of a coefficient of thermal expansion, a glass transition temperature, and a storage modulus. Since the insulating layer 10 including the epoxy resin and the liquid crystal oligomer has excellent heat-resisting property and modulus, it is not likely to be deformed by heat or physical force from the outside.

In addition, the insulating layer 10 may further include an inorganic filler in order to improve characteristic of the coefficient of thermal expansion. The insulating layer 10 may be an insulating film or a prepreg and the prepreg may include inorganic fiber or organic fiber.

Since the resin composition mentioned in the carrier 100 according to the preferred embodiment of the present invention is overlapped with that in the method of manufacturing the printed circuit board according to another preferred embodiment of the present invention, a description thereof will be omitted.

In the forming of the first metal layer 22, the first metal layer 22 may be formed so that a shiny surface of the first metal layer 22 is bonded to the insulating layer 10. The shiny surface of the first metal layer 22, which is a smooth portion, may be bonded to the insulating layer 10 and may be easily separated from the insulating layer 10. In the case in which the first metal layer 22 is formed on the insulating layer 10 and an additional build-up layer 80 is stacked on one surface of the other surface of the carrier 100, deformation caused by heat or physical impact may be prevented and a warpage phenomenon may be minimized.

In the forming of the second metal layer 33, the second metal layer 33 may be formed so that a matte surface of the first metal layer 22 is bonded to the second metal layer 33. The matte surface of the first metal surface 22, which is a rough and matte surface having roughness formed thereon, may be easily separated from the second metal layer 33 due to weak adhesive force between the metals even when being bonded to the second metal layer 33.

In addition, the method may include forming a build-up layer 80 including build-up insulating layers 51 and 53 and build-up circuit layers 72 and 74 on the second metal layer 33. As the build-up insulating layers 51 and 53, an insulating film or a prepreg may be used, and inorganic filler may be included in a resin composition. Here, one build-up layer 80 may be formed by forming the build-up circuit layer 72 and 74 on the build-up insulating layer 51 and 53.

In the carrier 100, the second metal layer 33 may be included as the circuit layer of the build-up layer 80 and a circuit pattern 60 may be formed in the second metal layer 33.

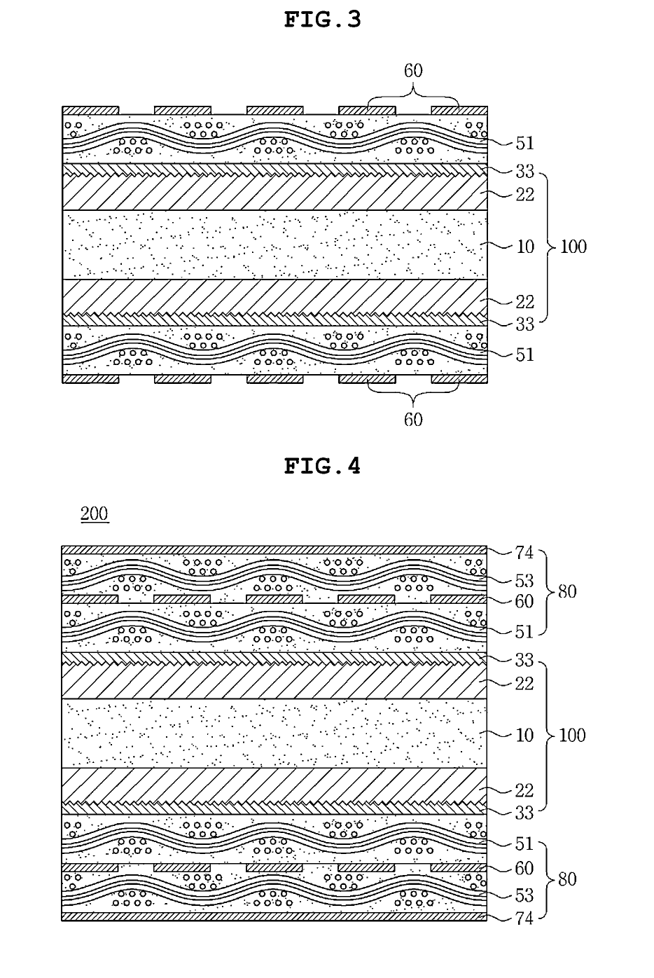

Referring to FIG. 3, in the method of manufacturing the printed circuit board according to another preferred embodiment of the present invention, the circuit pattern 60 may be formed in the build-up circuit layers 72 and 74 of the build-up layer 80. Thereby, at least one build-up layer 80 including the build-up insulating layers 51 and 53 and the build-up circuit layers 72 and 74 may be formed by an additional stacking process.

Referring to FIG. 4, in the method of manufacturing the printed circuit board according to another preferred embodiment of the present invention, a stacked body 200 having at least one build-up layer 80 formed thereon may be formed, where at least one build-up layer 80 includes the build-up layers 51 and 53 and the build-up circuit layers 72 and 74 formed on one surface of both surfaces of the carrier 100. At least one build-up layer 80 manufactured by the above-mentioned method may be used as a printed circuit board. In this case, the printed circuit board formed on one surface or both surfaces of the carrier 100 including the insulating layer including an epoxy resin and a liquid crystal oligomer, and the first metal layer uses the carrier 100 having improved heat-resisting property and modulus as a support, such that it may be protected from deformation caused by physical impact and may minimize a warpage phenomenon.

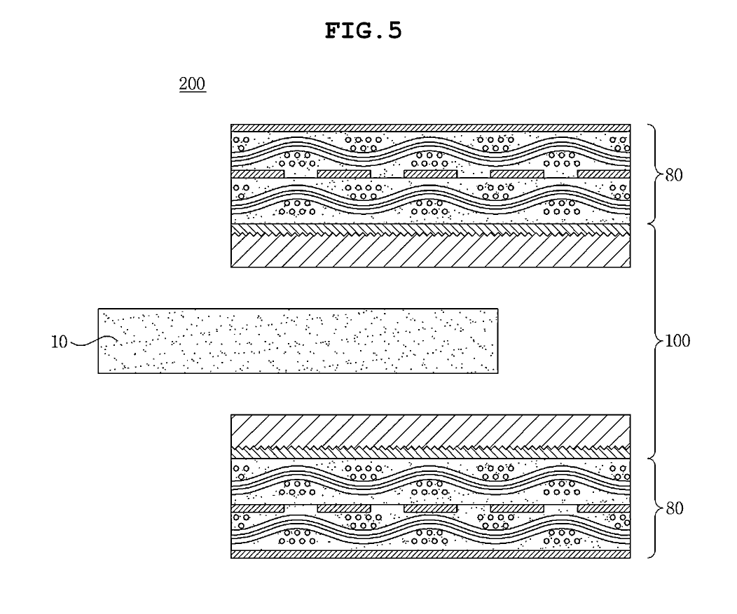

Referring to FIG. 5, the method of manufacturing the printed circuit board according to another preferred embodiment of the present invention may include separating the insulating layer 10 from the stacked body 200 having the build-up layer 80 formed thereon. The insulating layer 10 may be separated from the first metal layer 22. The insulating layer 10 may be separated by a method such as a blade cut method, or the like separating the insulating layer 10 from the first metal layer 22 by passing through a pointed instrument therebetween, but the separation method is not particularly limited thereto.

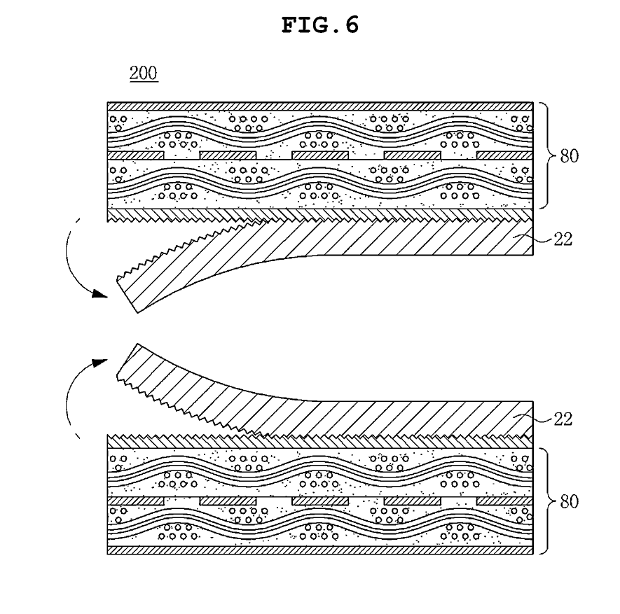

Referring to FIG. 6, the method of manufacturing the printed circuit board according to another preferred embodiment of the present invention may include separating the first metal layer 22 from the stacked body 200 having the build-up layer 80 formed thereon. The first metal layer 22 may be separated from the second metal layer 33. The first metal layer 22 may be separated by a method such as a peeling method, or the like stripping the first metal layer 22 by forming a gap between the first metal layer 22 and the second metal layer 33 and pulling the first metal layer 22, but the separation method is not particularly limited thereto.

Hereinafter, the present invention will be described in more detail through Inventive Examples and Comparative Examples but the scope of the present invention is not limited thereto.

### Preparation of Liquid Crystal Oligomer

### Preparing Example 1

4-aminophenol of 218.26 kg, isophthalic acid of 415.33 kg, 4-hydroxybenzoic acid of 276.24 kg, 6-hydroxy-2-naphthoic acid of 282.27 kg, DOPO-HQ of 648.54 kg, acetic acid anhydride of 1531.35 kg were added in a glass reactor of 10 to 20 l. Here, after sufficiently substituting nitrogen gas for an interior of the reactor, a temperature in the reactor was increased to a temperature of about 230° C. under flow of the nitrogen gas and was refluxed for about 4 hours while maintaining the temperature in the reactor at the 230° C. 6-hydroxy-2-naphthoic acid of 188.18 kg for capping an end was additionally added and acetic acid which is a by-product of the reaction and unreacted acetic acid anhydride were then removed, such that a liquid crystal oligomer was prepared. The liquid crystal oligomer has a number average molecular weight of about 3500 to 5000. The liquid crystal oligomer has viscosity of about 800 to 1000 cps under condition of 100 rpm when using a Brook field viscometer.

### Preparation of Varnish

### Preparing Example 2

A mixture mixing the liquid crystal oligomer of 240 kg prepared by the Preparing Example 1, bis(2,7-bis(2,3-epoxypropoxy))dinaphthalene methane which is a naphthalene based epoxy resin of 4-functional group of 80 kg, and spherical silica of 380 kg having a particle diameter of about 500 nm into N,N′-dimethylacetamide (DMAc) solvent of 335 kg was agitated by an agitator for about 2 hours. A dispersant and a silane coupling agent were additionally added to this mixture. A varnish of a resin composition was prepared by checking that the mixture was completely dissolved, adding dicyandiamid (DICY) of 0.8 kg which is a curing agent thereto, agitating it for about 1 hour, and then completely dissolving it.

### Manufacture of Carrier

### Manufacturing Example 3

The prepreg was prepared by pouring the varnish prepared by the Preparing Example 2 into an impregnating vessel of an impregnator by a suitable amount, immersing glass fiber into the varnish in the impregnating vessel, and then drying it. The carrier was manufactured by sequentially stacking a first metal layer (18 μm) and a second metal layer (2 μm) on both surfaces of the prepreg, increasing a temperature to about 220° C. in a stacking machine, maintaining the stacked first and second metal layers for about 90 minutes at the temperature of about 220° C. and a pressure of 30 kgf/cm², and then completely curing it.

### Inventive Example 1

Measurement samples are manufactured by cutting out the carrier manufactured by the Manufacturing Example 3 into a size of about 4.3 mm/30 mm.

### Comparative Example 1

A mixture mixing an epoxy resin Araldite MY-721 having 2-functional group (prepared by Huntsman Company) of 80 kg, and spherical silica of 186 kg having a particle diameter of about 500 nm into N,N′-dimethylacetamide (DMAc) solvent of 46.5 kg was agitated by an agitator for about 2 hours. A dispersant and a silane coupling agent were additionally added to this mixture.

A varnish of a resin composition was prepared by checking that the mixture was completely dissolved, adding dicyandiamid (DICY) of 0.5 kg which is a curing agent thereto, agitating it for about 1 hour, and then completely dissolving it.

Here, the carrier was manufactured by fabricating the varnish prepared by Comparative Example 1 in the same method as in Manufacturing Example 3. Thereby, measurement samples are manufactured by cutting out the carrier into a size of about 4.3 mm/30 mm.

Coefficients of thermal expansion of the samples manufactured by Inventive Example 1 and Comparative Example 1 were measured in a tensile mode using a TMA equipment manufactured by the TA Company. In addition, modulus was measured in a tension mode using a DMA equipment from the TA Company and was scanned up to 350° C. by 3° C. per minute, and a glass transition temperature was measure by calculating an initial storage modulus and a maximum value of tan δ (ratio of loss modulus to storage modulus).

TABLE 1

| | Storage | Coefficient of | Glass Transition |
|---|---|---|---|
| | Modulus | Thermal Expansion | Temperature |
| Classification | (GPa) | (ppm/° C.) | (° C.) |
| Inventive | 25.0 | 9.0 | 200 |
| Example 1 | | | |
| Comparative | 23.0 | 13.0 | 150 |
| Example 1 | | | |

It may be appreciated from Table 1 that Inventive Example 1 has more excellent characteristics of the storage modulus, the coefficient of thermal expansion, and the glass transition temperature than Comparative Example 1. Thereby, the carrier manufactured by Inventive Example 1 may provide the carrier having characteristics of the coefficient of thermal expansion, the glass transition temperature, and the storage modulus which are improved by the insulating layer including the epoxy resin and the liquid crystal oligomer.

In addition, the first metal layer is formed on the insulating layer, such that the printed circuit board stacked on one surface or both surfaces of the carrier may be protected from deformation by physical impact and the warpage phenomenon may be minimized.

According to the preferred embodiment of the present invention, the carrier may have characteristics of the coefficient of thermal expansion (CTE), the glass transition temperature (Tg), and the storage modulus which are improved by the insulating layer including the epoxy resin and the liquid crystal oligomer.

In addition, in the carrier according to the preferred embodiment of the present invention, the first metal layer is formed on the insulating layer, such that the printed circuit board stacked on one surface or both surfaces of the carrier may be protected from deformation by physical impact and the warpage phenomenon may be minimized.

In the method of manufacturing the printed circuit board according to another preferred embodiment of the present invention, the printed circuit board formed to be stacked on one surface or both surfaces of the carrier may minimize the deformation caused by outside force or heat.

Although the embodiments of the present invention have been disclosed for illustrative purposes, it will be appreciated that the present invention is not limited thereto, and those skilled in the art will appreciate that various modifications, additions and substitutions are possible, without departing from the scope and spirit of the invention.

Accordingly, any and all modifications, variations or equivalent arrangements should be considered to be within the scope of the invention, and the detailed scope of the invention will be disclosed by the accompanying claims.

What is claimed is:

1. A carrier, comprising:
an insulating layer;
a first metal layer formed on one surface or the other surface of the insulating layer; and
a second metal layer formed on one surface or the other surface of the first metal layer,
wherein the insulating layer includes an epoxy resin and a liquid crystal oligomer (LCO).

2. The carrier as set forth in claim 1, wherein the first metal layer has a shiny surface bonded to the insulating layer.

3. The carrier as set forth in claim 1, wherein the second metal layer has a matte surface of the first metal layer bonded thereto.

4. The carrier as set forth in claim 1, wherein the insulating layer is an insulating film or a prepreg.

5. The carrier as set forth in claim 4, wherein the prepreg includes inorganic fiber or organic fiber.

6. The carrier as set forth in claim 5, wherein the inorganic fiber or organic fiber is at least one selected from glass fiber, carbon fiber, polyparaphenylenebenzobisoxazole fiber, thermotropic liquid crystal polymer fiber, lyotropic liquid crystal polymer fiber, aramid fiber, polypyridobisimidazole fiber, polybenzothiazole fiber, and polyacrylate fiber.

7. The carrier as set forth in claim 1, wherein the first metal layer has a thickness thicker than that of the second metal layer.

8. The carrier as set forth in claim 1, wherein the first metal layer and the second metal layer are made of copper (Cu).

9. The carrier as set forth in claim 1, wherein the epoxy resin is at least one selected from a naphthalene-based epoxy resin, a bisphenol A-type epoxy resin, a bisphenol F-type epoxy resin, a phenol novolac epoxy resin, a cresol novolac epoxy resin, a rubber-modified epoxy resin, and a phosphate-based epoxy resin.

10. The carrier as set forth in claim 1, wherein the liquid crystal oligomer is represented by the following Chemical Formula 1, 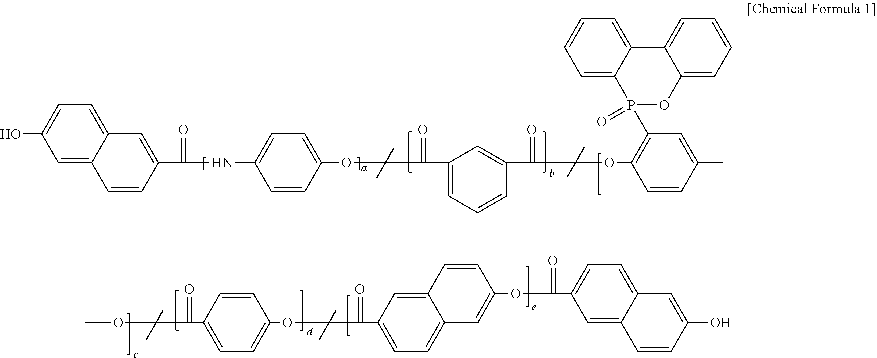
wherein a is an integer of 13 to 26, b is an integer of 13 to 26, c is an integer of 9 to 21, d is an integer of 10 to 30, and e is an integer of 10 to 30.

11. The carrier as set forth in claim 1, wherein the insulating layer further includes an inorganic filler.

12. The carrier as set forth in claim 11, wherein the organic filler is at least one selected from silica (SiO₂), alumina (Al₂O₃), barium sulfate (BaSO₄), talc, aluminum hydroxide (AlOH₃), magnesium hydroxide (Mg(OH)₂), calcium carbonate (CaCO₃), magnesium carbonate (MgCO₃), magnesium oxide (MgO), boron nitride (BN), aluminum borate (AlBO₃), barium titanate (BaTiO₃), and calcium zirconate (CaZrO₃).

13. A method of manufacturing a printed circuit board, the method comprising:
preparing a carrier including an insulating layer, a first metal layer formed on one surface or the other surface of the insulating layer, and a second metal layer formed on one surface or the other surface of the first metal layer, the insulating layer including an epoxy resin and a liquid crystal oligomer (LCO);
forming at least one build-up layer including build-up insulating layers and build-up circuit layers on the second metal layer; and
separating the insulating layer and the first metal layer from a stacked body having the build-up layer formed thereon.

14. The method as set forth in claim 13, wherein the epoxy resin is at least one selected from a naphthalene-based epoxy resin, a bisphenol A-type epoxy resin, a bisphenol F-type epoxy resin, a phenol novolac epoxy resin, a cresol novolac epoxy resin, a rubber-modified epoxy resin, and a phosphate-based epoxy resin.

15. The method as set forth in claim 13, wherein the liquid crystal oligomer is represented by the following Chemical Formula 1, 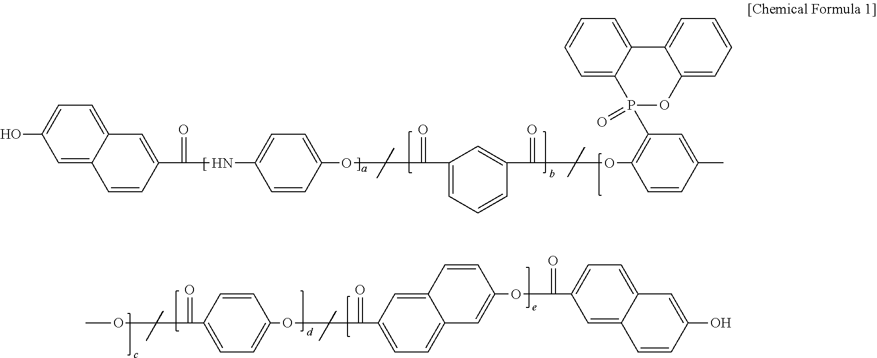
wherein a is an integer of 13 to 26, b is an integer of 13 to 26, c is an integer of 9 to 21, d is an integer of 10 to 30, and e is an integer of 10 to 30.

16. The method as set forth in claim 13, wherein the insulating layer is an insulating film or a prepreg.

17. The method as set forth in claim 13, wherein a shiny surface of the first metal layer is bonded to the insulating layer.

18. The method as set forth in claim 13, wherein a matte surface of the first metal layer is bonded to the second metal layer.

19. The method as set forth in claim 13, wherein the separating of the insulating layer and the first metal layer from the stacked body includes:
separating the insulating layer from the first metal layer, and
separating the first metal layer from the second metal layer.
